(19) United States
(12) Patent Application Publication
(10) Pub. No.: US 2023/0107892 A1
(43) Pub. Date: Apr. 6, 2023

(54) NEGATIVE TYPE PHOTOSENSITIVE COMPOSITION COMPRISING REFLECTANCE MODIFIER

(71) Applicant: Merck Patent GmbH, Darmstadt (DE)

(72) Inventors: Suryani LIN, Hukou Township (TW); Yi-Meng YEN, Hukou Township (TW); Yung-Cheng CHANG, Hukou Township (TW); Daishi YOKOYAMA, Kakegawa-Shi (JP); Atsuko NOYA, Kakegawa-shi (JP)

(21) Appl. No.: 17/909,999

(22) PCT Filed: Mar. 5, 2021
(86) PCT No.: PCT/EP2021/055554

§ 371 Date: Sep. 8, 2022

(30) Foreign Application Priority Data
Mar. 9, 2020 (JP) 2020-039928

(51) Int. Cl. G03F 7/038

(52) U.S. Cl. CPC G03F 7/0382

(57) ABSTRACT

To provide a negative type photosensitive composition which is capable of forming a cured film having good light shielding properties and high reflectance. [Means for Solution] A negative type photosensitive composition comprising an alkali-soluble resin having a particular structure, a reflectance modifier, a polymerization initiator, and a solvent.

### BACKGROUND OF THE INVENTION

### Technical Field

The present invention relates to a negative type photosensitive composition comprising a reflectance modifier. Further, the present invention relates also to a method for producing a cured film using the same, a cured film formed therefrom, and a device comprising the cured film.

### Background Art

In display devices such as an organic electroluminescence devices (OLED), partition walls are formed in order to divide between the pixels. This partition walls are generally formed by photolithography using photosensitive resin compositions.

As partition wall materials, transparent materials have been used. In order to further enhance the contrast, colored partition walls in which partition wall materials have light shielding properties have been studied. For example, a black partition wall using a photosensitive resin composition comprising a black colorant has been studied. A white partition wall is also required.

Using a photosensitive resin composition containing a white colorant adversely affects patterning, since the white colorant reflects light during exposure and light does not reach the bottom of the coating film of the photosensitive resin composition. Thus, such a composition is hard to achieve higher resolution. A material capable of achieving a thicker film is required as an OLED partition wall material of a display device or an overcoat material. However, when a photosensitive resin composition containing a white colorant is used for making a thick film, influence of the reflection by the white colorant becomes more than that of a thin film.

In addition, when partition walls are white, the partition walls are required to have high reflectance.

### PRIOR ART DOCUMENTS

### Patent Documents

[Patent document 1] WO 2018/056189
[Patent document 2] JP 2015-69085 A

### SUMMARY OF THE INVENTION

### Problems to be Solved by the Invention

The present invention has been made in view of the above-described circumstances, and its object is to provide a negative type photosensitive composition which is capable of forming a cured film having high resolution, good light shielding properties, and high reflectance.

### Means for Solving the Problems

The negative type photosensitive composition according to the present invention comprises

(I) an alkali-soluble resin comprising a polymer comprising a repeating unit represented by formula (A):

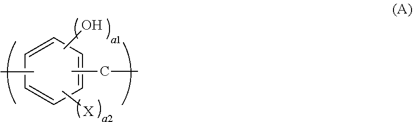

wherein,
X is each independently a C₁₋₂₇ substituted or unsubstituted hydrocarbon group,
a1 is 1 to 2, and
a2 is 0 to 3,
(II) a reflectance modifier,
(III) a polymerization initiator, and
(IV) a solvent.

The method for producing a cured film according to the present invention comprises applying the above described composition on a substrate to form a coating film, exposing the film, and heating the film.

The cured film according to the present invention is produced by the above described method.

The device according to the present invention is one comprising the above described cured film.

### Effects of the Invention

The negative type photosensitive composition according to the present invention can form a cured film having high resolution, good light shielding properties, and high reflectance. Further, the negative type photosensitive composition according to the present invention can form a thick film.

### DETAILED DESCRIPTION OF THE INVENTION

### Mode for Carrying Out the Invention

Embodiments of the present invention are described below in detail.

In the present specification, symbols, units, abbreviations, and terms have the following meanings unless otherwise specified.

In the present specification, unless otherwise specifically mentioned, the singular form includes the plural form and “one” or “that” means “at least one”. In the present specification, unless otherwise specifically mentioned, an element of a concept can be expressed by a plurality of species, and when the amount (for example, mass % or mol %) is described, it means sum of the plurality of species. “And/or” includes a combination of all elements and also includes single use of the element.

In the present specification, when a numerical range is indicated using “to” or “−”, it includes both endpoints and units thereof are common. For example, 5 to 25 mol % means 5 mol % or more and 25 mol % or less.

In the present specification, the hydrocarbon means one including carbon and hydrogen, and optionally including oxygen or nitrogen. The hydrocarbyl group means a monovalent or divalent or higher valent hydrocarbon. In the present specification, the aliphatic hydrocarbon means a linear, branched or cyclic aliphatic hydrocarbon, and the aliphatic hydrocarbon group means a monovalent or divalent or higher valent aliphatic hydrocarbon. The aromatic hydrocarbon means a hydrocarbon comprising an aromatic ring which may optionally not only comprise an aliphatic hydrocarbon group as a substituent but also be condensed with an alicycle. The aromatic hydrocarbon group means a monovalent or divalent or higher valent aromatic hydrocarbon. Further, the aromatic ring means a hydrocarbon comprising a conjugated unsaturated ring structure, and the alicycle means a hydrocarbon having a ring structure but comprising no conjugated unsaturated ring structure.

In the present specification, the alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and optionally includes a linear or branched alkyl in the cyclic structure as a side chain.

In the present specification, the aryl means a group obtained by removing any one hydrogen from an aromatic hydrocarbon. The alkylene means a group obtained by removing any two hydrogens from a linear or branched, saturated hydrocarbon. The arylene means a hydrocarbon group obtained by removing any two hydrogens from an aromatic hydrocarbon.

In the present specification, the descriptions such as “C_{x-y}”, “Cₓ-C_{y}” and “Cₓ” mean the number of carbons in the molecule or substituent group. For example, C₁₋₆ alkyl means alkyl having 1 to 6 carbons (such as methyl, ethyl, propyl, butyl, pentyl and hexyl). Further, the fluoroalkyl as used in the present specification refers to one in which one or more hydrogen in alkyl is replaced with fluorine, and the fluoroaryl is one in which one or more hydrogen in aryl are replaced with fluorine.

In the present specification, when polymer has a plural types of repeating units, these repeating units copolymerize. These copolymerization are any of alternating copolymerization, random copolymerization, block copolymerization, graft copolymerization, or a mixture of any of these.

In the present specification, “%” represents mass % and “ratio” represents ratio by mass.

In the present specification, Celsius is used as the temperature unit. For example, 20 degrees means 20 degrees Celsius.

### <Negative Type Photosensitive Composition>

The negative type photosensitive composition according to the present invention (hereinafter sometimes referred to as the composition) comprises a particular alkali-soluble resin, a reflectance modifier, a polymerization initiator, and a solvent. Hereinafter, each component contained in the composition according to the present invention is described in detail.

The composition according to the present invention is a negative type photosensitive composition for a thick film which exhibits effects as long as it is a film having a thickness of 100 μm or less, and in particular exhibits effects when it is used for a thick film such as a partition material. In the present invention, the thick film means a film having an average film thickness of 5 to 100 μm (preferably 5 to 25 μm, more preferably 8 to 20 μm). In the present invention, the average film thickness is determined by measuring the film thicknesses at 3 to 5 points using a stylus type surface profile measuring instrument of ULBAC to calculate an average value of them.

### (I) Alkali-Soluble Resin

The alkali-soluble resin used in the present invention comprises a particular polymer comprising a repeating unit represented by formula (A). Hereinafter, an alkali-soluble resin comprising a repeating unit represented by formula (A) is sometimes referred to as polymer A.

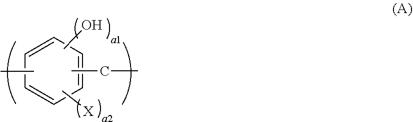

### Wherein,

X is each independently a C₁₋₂₇ substituted or unsubstituted hydrocarbon group,
a1 is 1 to 2, preferably 1, and
a2 is 0 to 3, preferably 1.

This polymer A can be a novolac polymer widely used in lithography, and can be obtained, for example, by a condensation reaction of phenols with formaldehyde.

The composition according to the present invention comprises a reflectance modifier.

White colorants typically reflect not only visible light but also ultraviolet light. In this case, when a composition comprising a white colorant apply to a substrate to form a coating film, the white colorant reflects ultraviolet light by exposure, light does not reach the bottom of the coating film, and therefore no pattern formation can be resulted.

However, the composition according to the present invention can achieve higher resolution by comprising a polymer having a structure represented by formula (A) in addition to a reflectance modifier. Without wishing to be bound by theory, it is considered due to following. When a composition comprising a polymer having a structure represented by formula (A) is applied on a substrate to form a coating film, transmittance of the coating film is high due to low ultraviolet light absorption during exposure, and the light reach the bottom of the coating film, and therefore pattern formation can be achieved. After the pattern formation, when the coating film is heated at high temperature, a methylene group of formula (A) is oxidized, absorption of ultraviolet light increases, and therefore, a cured film having a low transmittance and a high reflectance can be formed.

When thicker film is preferred, X preferably comprises a bulky group. In particular, at least one X is preferably represented by -L-Ar. L is a C₁₋₈ linear or branched alkylene, preferably C₃₋₆ branched alkylene. Examples of L include —C(CH₃)₂— and cyclohexane.

Ar is a C₆₋₂₂ substituted or unsubstituted aryl, preferably C₆₋₁₀ substituted or unsubstituted phenyl, where a substitution group is hydroxy or a C₁₋₈ alkyl. Examples of Ar include following.

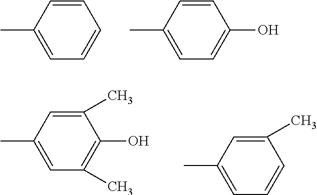

In a preferable embodiment, the alkali-soluble resin used in the present invention comprises a repeating unit represented by formula (A-1).

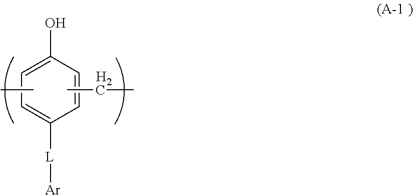

Wherein L and Ar are as described above.

Preferably, the alkali-soluble resin used in the present invention further comprises a repeating unit represented by formula (A-2), in addition to the repeating unit represented by formula (A-1).

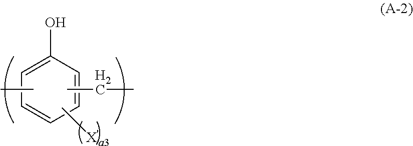

### Wherein,

X′ is each independently a C₁₋₈ unsubstituted alkyl, preferably methyl or ethyl, and
a3 is 0 to 3, preferably 0 to 2, more preferably 1.

The ratio of the repeating unit represented by formula (A-1) in polymer A is preferably 1 to 100%, more preferably 10 to 90%, further preferably 40 to 80%, based on the total number of repeating units contained in polymer A. The ratio of the repeating unit represented by formula (A-2) in polymer A is preferably 0 to 90%, more preferably 10 to 90%, based on the total number of repeating units contained in polymer A. Polymer A can further comprise repeating units other than the repeating units represented by formulae (A-1) and (A-2). The repeating units other than the repeating units represented by formulae (A-1) and (A-2) is preferably 20% or less, more preferably 10% or less, based on the total number of repeating units contained in polymer A. It is also a preferable embodiment of the present invention that no repeating unit other than the repeating units represented by formulae (A-1) and (A-2) is comprised.

The mass average molecular weight (hereinafter sometimes referred to as Mw) of polymer A is preferably 5,000 to 30,000, more preferably 6,000 to 15,000, further preferably 8,200 to 11,500. Here, the mass average molecular weight is a mass average molecular weight in terms of polystyrene, which can be measured by gel permeation chromatography based on polystyrene. The same applies to the following description.

The alkali-soluble resin used in the present invention can be a mixture of two or more kinds of polymer A or a mixture further comprising a polymer different from polymer A, that is, a polymer comprising no repeating unit represented by formula (A). Preferably, the alkali-soluble resin used in the present invention further comprises a polysiloxane and/or an acrylic polymer. From the viewpoint of the dispersibility and heat resistance of the reflectance modifier, it is more preferable to use a polysiloxane.

### (Polysiloxane)

The polysiloxane used in the present invention is not particularly limited, and can be selected, depending on the purpose, from any one. Depending on the number of the oxygen atoms bonded to a silicon atom, the skeleton structure of polysiloxane can be classified as follows: a silicone skeleton (the number of oxygen atoms bonded to a silicon atom is 2), a silsesquioxane skeleton (the number of oxygen atoms bonded to a silicon atom is 3), and a silica skeleton (the number of oxygen atoms bonded to a silicon atom is 4). In the present invention, any of these can be used. The polysiloxane molecule can contain a combination of a plurality of these skeleton structures.

The polysiloxane used in the present invention preferably comprises a repeating unit represented by the following formula (Ia).

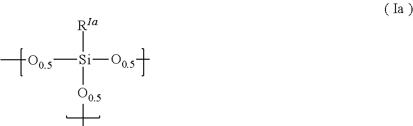

### Wherein,

R^{Ia} represents hydrogen, a C₁₋₃₀ (preferably C₁₋₁₀) linear, branched or cyclic, saturated or unsaturated, aliphatic hydrocarbon group or aromatic hydrocarbon group, the aliphatic hydrocarbon group and the aromatic hydrocarbon group are each unsubstituted or substituted with fluorine, hydroxy, or C₁₋₈ alkoxy, and in the aliphatic hydrocarbon group and the aromatic hydrocarbon group, methylenes are not replaced, or one or more methylene is replaced with oxy, imino or carbonyl, provided that R^{Ia} is neither hydroxy nor alkoxy. The above-described methylene group includes terminal methyl.

Further, the above “substituted with fluorine, hydroxy, or C₁₋₈ alkoxy” means that a hydrogen atom directly bonded to a carbon atom in an aliphatic hydrocarbon group or an aromatic hydrocarbon group is replaced with fluorine, hydroxy, or C₁₋₈ alkoxy. In the present specification, the same applies to other similar descriptions.

In the repeating unit represented by the formula (Ia), examples of R^{Ia} include (i) alkyl such as methyl, ethyl, propyl, butyl, pentyl, hexyl, heptyl, octyl and decyl, (ii) aryl such as phenyl, tolyl and benzyl, (iii) fluoroalkyl such as trifluoromethyl, 2,2,2-trifluoroethyl and 3,3,3-trifluoropropyl, (iv) fluoroaryl, (v) cycloalkyl such as cyclohexyl, (vi) a nitrogen-containing group having an amino or imide structure such as isocyanate and amino, and (vii) an oxygen-containing group having an epoxy structure such as glycidyl, or an acryloyl or methacryloyl structure. Preferred are methyl, ethyl, propyl, butyl, pentyl, hexyl, and phenyl. It is preferable that R^{Ia} is methyl, because the raw material is easy to obtain, the film hardness after cured is high, and the chemical resistance is high. Further, it is preferable that R^{Ia} is phenyl, because the solubility of the polysiloxane in the solvent is increased and the cured film is less likely to crack.

The polysiloxane used in the present invention can comprise a repeating unit represented by the following formula (Ib).

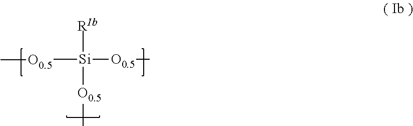

### Wherein,

R^{Ib} is a group obtained by removing a plurality of hydrogens from a nitrogen- and/or oxygen-containing alicyclic hydrocarbon compound containing amino, imino and/or carbonyl.

In the formula (Ib), R^{Ib} is preferably a group obtained by removing a plurality of, preferably two or three of hydrogen atoms, preferably from a nitrogen-containing aliphatic hydrocarbon compound containing imino and/or carbonyl, and more preferably from a 5-membered ring or a 6-membered ring containing nitrogen as a member. For example, a group obtained by removing two or three hydrogens from piperidine, pyrrolidine and isocyanurate can be mentioned. R^{Ib} connects each Si included in a plurality of repeating units.

The polysiloxane used in the present invention can further comprise a repeating unit represented by the formula (Ic).

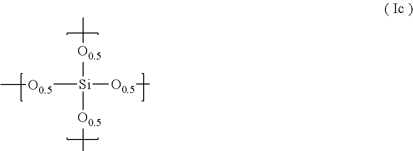

Since photosensitivity of the composition decrease, and cracks easily occur due to decrease of the compatibility with solvents and additives and increase of the film stress when the mixing ratio of the repeating units represented by the formulae (Ib) and (Ic) is high, it is preferably 40 mol % or less, more preferably 20 mol % or less, based on the total number of the repeating units of polysiloxane.

The polysiloxane used in the present invention can further comprise a repeating unit represented by the formula (Id).

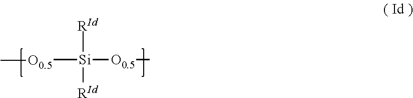

### Wherein,

R^{Id} each independently represents hydrogen, a C₁₋₃₀ (preferably C₁₋₁₀) linear, branched or cyclic, saturated or unsaturated, aliphatic hydrocarbon group or aromatic hydrocarbon group,
the aliphatic hydrocarbon group and the aromatic hydrocarbon group are each unsubstituted or substituted with fluorine, hydroxy, or C₁₋₈ alkoxy, and
in the aliphatic hydrocarbon group and the aromatic hydrocarbon group, methylenes are not replaced, or one or more methylene is replaced with oxy, imide, or carbonyl, provided that R^{Id} is neither hydroxy nor alkoxy.

In the repeating unit represented by the formula (Id), examples of R^{Id} include (i) alkyl such as methyl, ethyl, propyl, butyl, pentyl, hexyl, heptyl, octyl and decyl, (ii) aryl such as phenyl, tolyl and benzyl, (iii) fluoroalkyl such as trifluoromethyl, 2,2,2-trifluoroethyl and 3,3,3-trifluoropropyl, (iv) fluoroaryl, (v) cycloalkyl such as cyclohexyl, (vi) a nitrogen-containing group having an amino or imide structure such as isocyanate and amino, and (vii) an oxygen-containing group having an epoxy structure such as glycidyl, or an acryloyl or methacryloyl structure. Preferred are methyl, ethyl, propyl, butyl, pentyl, hexyl, and phenyl. It is preferable that R^{Id} is methyl, because the raw material is easy to obtain, the film hardness after cured is high, and the chemical resistance is high. Further, it is preferable that R^{Id} is phenyl, because the solubility of the polysiloxane in the solvent is increased and the cured film is less likely to crack.

Through having the repeating unit represented by the above described formula (Id), the polysiloxane used in the present invention can partially have a linear structure. However, since the heat resistance is reduced, it is preferable that the linear structure portion is less. In particular, the repeating unit represented by the formula (Id) is preferably 30 mol % or less, more preferably 5 mol % or less, based on the total number of the repeating units of polysiloxane. It is also an aspect of the present invention that polysiloxane comprises no repeating unit represented by the formula (Id) (0 mol %).

The polysiloxane used in the present invention can comprise two or more kinds of repeating units. For example, the polysiloxane having 3 kinds of repeating units which are the repeating units represented by formula (Ia) wherein R^{Ia} is methyl and phenyl and the repeating unit represented by formula (Ic) is included.

The polysiloxane used in the present invention preferably has silanol. Silanol means OH group bonded directly to Si back bone of polysiloxane. In the polysiloxane comprising repeating units such as formulae (Ia) to (Id), hydroxy bonds directly to a silicon atom. That is, silanol is formed by bonding —O_{0.5}H to —O_{0.5}— of the above formulae (Ia) to (Id). The content of silanol in polysiloxane varies depending on the synthesis conditions, for example monomer blending ratio and kinds of reaction catalyst.

The mass average molecular weight of the polysiloxane used in the present invention is not particularly limited. However, the higher the molecular weight is, the more the coating properties tend to be improved. On the other hand, the lower the molecular weight is, the less the synthesis conditions are limited and the easier the synthesis is, and it is difficult to synthesize polysiloxane having a very high molecular weight. For these reasons, the mass average molecular weight of polysiloxane is usually 500 to 25,000, and preferably 1,000 to 20,000 in view of the solubility in an organic solvent and the solubility in an alkali developer. Here, the mass average molecular weight is a mass average molecular weight in terms of polystyrene, which can be measured by gel permeation chromatography based on polystyrene.

The synthesis method of the polysiloxane used in the present invention is not particularly limited. For example, it can be synthesized according to the method disclosed in JP 6639724 B.

### (Acrylic Polymer)

The acrylic polymer used in the present invention can be selected from generally used acrylic polymer, for example, polyacrylic acid, polymethacrylic acid, polyalkyl acrylate, polyalkyl methacrylate, and the like. The acrylic polymer used in the present invention preferably comprises a repeating unit containing an acryloyl group, and also preferably further comprises a repeating unit containing a carboxy group and/or a repeating unit containing an alkoxysilyl group.

Although the repeating unit containing a carboxy group is not particularly limited as long as it is a repeating unit containing a carboxy group at its side chain, a repeating unit derived from an unsaturated carboxylic acid, an unsaturated carboxylic anhydride or a mixture thereof is preferable.

Although the repeating unit containing an alkoxysilyl group can be a repeating unit containing an alkoxysilyl group at its side chain, it is preferably a repeating unit derived from a monomer represented by the following formula (B).

X^{B}—(CH₂)ₐ—Si(OR^{B})_{b}(CH₃)_{3-b} (B)

### Wherein,

X^{B} is a vinyl group, a styryl group or a (meth)acryloyloxy group, R^{B} is a methyl group or an ethyl group, a is an integer of 0 to 3, and b is an integer of 1 to 3.

Further, it is preferable that the above-described polymer contains a repeating unit containing a hydroxy group, which is derived from a hydroxy group-containing unsaturated monomer.

The mass average molecular weight of the alkali-soluble resin according to the present invention is not particularly limited, and is preferably 1,000 to 40,000, more preferably 2,000 to 30,000. Here, the mass average molecular weight is a mass average molecular weight in terms of polystyrene according to gel permeation chromatography. In addition, as far as the number of acid groups is concerned, the solid content acid value is usually 40 to 190 mgKOH/g, more preferably 60 to 150 mgKOH/g, from the viewpoint of enabling development with a low-concentration alkaline developer and achieving both reactivity and storage stability.

When a mixture of a polysiloxane and an acrylic polymer in addition to polymer A is used as the alkali-soluble resin, the mixing ratio of the polysiloxane and the acrylic polymer is not particularly limited. When the coating film is thickened, it is preferable that the mixing ratio of the acylic polymer is high. On the other hand, when the composition is applied to high temperature process, it is preferable that the mixing ratio of the polysiloxane is high, in view of transparency and chemical resistance after curing. For these reasons, the mixing ratio of the polysiloxane:the acrylic polymer is preferably 90:10 to 10:90, and more preferably 85:15 to 25:75.

Polymer A can be a copolymer further comprising a repeating unit represented by above formulae (Ia) to (Id), which is a back bone of polysiloxane, or a repeating unit which is a back bone of acrylic polymer.

Further, a cured film is formed through application of the composition according to the present invention onto a substrate, imagewise exposure, and development. At this time, it is necessary that a difference in solubility occurs between the exposed area and the unexposed area, and the coating film in the unexposed area should have a certain or more solubility in a developer. For example, it is considered that a pattern can be formed by exposure and development if dissolution rate of the coating film after prebaked, in a 2.38% tetramethylammonium hydroxide (hereinafter sometimes referred to as TMAH) aqueous solution (hereinafter sometimes referred to as alkali dissolution rate or ADR, which is described later in detail) is 50 Å/sec or more. However, since the required solubility varies depending on the film thickness of the cured film to be formed and the development conditions, the alkali-soluble resin should be appropriately selected according to the development conditions. Although it varies depending on the type and addition amount of the photosensitizer or the silanol catalyst contained in the composition, for example, if the film thickness is 0.1 to 100 μm (1,000 to 1,000,000 Å), the dissolution rate in a 2.38% TMAH aqueous solution is preferably 50 to 20,000 Å/sec, and more preferably 100 to 10,000 Å/sec.

### [Measurement of Alkaline Dissolution Rate (ADR) and Calculation Method Thereof]

Using a TMAH aqueous solution as an alkaline solution, the alkali dissolution rate of the alkali-soluble resin is measured and calculated as described below.

The alkali-soluble resin is diluted with propylene glycol monomethyl ether acetate (hereinafter sometimes referred to as PGMEA) so as to be 35 mass % and dissolved while stirring at room temperature with a stirrer for 1 hour. In a clean room under an atmosphere of temperature of 23.0±0.5° C. and humidity of 50±5.0%, using a pipette, 1 cc of the prepared alkali-soluble resin solution is dropped on the center area of a 4-inch silicon wafer having a thickness of 525 μm and spin-coated to make a film having a thickness of 2±0.1 μm, and then the film is heated on a hot plate at 100° C. for 90 seconds to remove the solvent. The film thickness of the coating film is measured with a spectroscopic ellipsometer (manufactured by J.A. Woollam).

Next, the silicon wafer having this film is gently immersed in a glass petri dish having a diameter of 6 inches, into which 100 ml of a TMAH aqueous solution adjusted to 23.0±0.1° C. and having a predetermined concentration was put, then allowed to stand, and the time until the coating film disappears is measured. The dissolution rate is determined by dividing by the time until the film in the area of 10 mm inside from the wafer edge disappears. In the case that the dissolution rate is remarkably slow, the wafer is immersed in a TMAH aqueous solution for a certain period and then heated for 5 minutes on a hot plate at 200° C. to remove moisture taken in the film during the dissolution rate measurement. Thereafter, film thickness is measured, and the dissolution rate is calculated by dividing the amount of change in film thickness before and after the immersion, by the immersion time. The above measurement method is performed 5 times, and the average of the obtained values is taken as the dissolution rate of the alkali-soluble resin.

### (II) Reflectance Modifier

The composition according to present invention comprises a reflectance modifier. In the present invention, the reflectance modifier is a substance that can form a cured film having low transmittance and high reflectance, in combination with polymer A. The color of the reflectance modifier is not particularly limited, but the reflectance modifier is preferably colored in white by absorbing light having a wavelength of 370 to 740 nm.

The reflectance modifier can be an inorganic pigment or an organic pigment, or a combination of two or more pigment. In the present invention, an inorganic pigment is preferred because of the high scattering property.

Examples of the inorganic pigment include alumina, magnesium oxide, antimony oxide, zirconium oxide, aluminum hydroxide, magnesium hydroxide, barium sulfate, magnesium carbonate, barium carbonate, calcium carbonate, lead sulfate, lead phosphate, zinc phosphate, silicon dioxide, zinc oxide, tin oxide, strontium sulfide, strontium titanate, barium tungstate, lead metasilicate, talc, kaolin, clay, bismuth chloride oxide, silica (for example hollow silica particle), titanium oxide, titanium oxynitride, titanium nitride. Preferably, the inorganic pigment is selected from at least one of the group consisting of alumina, magnesium oxide, antimony oxide, titanium oxide, titanium oxynitride, titanium nitride, zirconium oxide, aluminum hydroxide, magnesium hydroxide, barium sulfate, magnesium carbonate, and barium carbonate. From the viewpoint of particle size control, it is particularly preferable to use titanium oxide. These pigments can be core-shell type.

Examples of the organic pigment include organic compound salts disclosed in JP H11-129613 A, alkylene bismelamine derivatives, and hollow particles using thermoplastic resin such as styrene-acrylic copolymer.

The volume-based average particle diameter (herein after sometimes referred to as average particle diameter) of the reflectance modifier is preferably 50 to 900 nm, more preferably 50 to 700 nm. When the particle diameter is within the above range, obtained cured film can have good shielding properties and good film quality. This average particle diameter can be measured using equipments such as Nano Trac Wave (NIKKISO CO., LTD.) in accordance with Dynamic Light Scattering (DLS) method.

The content of the reflectance modifier used in the present invention is preferably 10 to 150 mass %, more preferably 20 to 110 mass %, based on the total mass of the alkali-soluble resin.

The content of the reflectance modifier is based on the mass of the pigment itself. That means that, in some cases, the reflectance modifier is obtained in a dispersed state using a dispersant, and in this case, the mass of the black colorant does not include anything other than the pigment.

The reflectance modifier used in the present invention can be used in combination with a dispersant. As the dispersant, an organic compound-based dispersant such as a polymer dispersant described, for example, in JP-A 2004-292672 can be used.

### (III) Polymerization Initiator

The composition according to the present invention comprises a polymerization initiator. The polymerization initiator includes a polymerization initiator that generates an acid, a base or a radical by radiation, and a polymerization initiator that generates an acid, a base or a radical by heat. In the present invention, the former is preferable and the photo radical generator is more preferable, in terms of process shortening and cost since the reaction is initiated immediately after the radiation irradiation and the reheating process performed after the radiation irradiation and before the developing process can be omitted.

The photo radical generator can improve the resolution by strengthening the pattern shape or increasing the contrast of development. The photo radical generator used in the present invention is a photo radical generator that emits a radical when irradiated with radiation. Here, examples of the radiation include visible light, ultraviolet light, infrared light, X-ray, electron beam, α-ray, and γ-ray.

The addition amount of the photo radical generator is preferably 0.001 to 50 mass %, more preferably 0.01 to 30 mass %, based on the total mass of the alkali-soluble resin, though the optimal amount thereof depends on the type and amount of active substance generated by decomposition of the photo radical generator, the required photosensitivity, and the required dissolution contrast between the exposed area and unexposed area. If the addition amount is less than 0.001 mass %, the dissolution contrast between the exposed area and unexposed portion is too low, and the addition effect is not sometimes exhibited. On the other hand, when the addition amount of the photo radical generator is more than 50 mass %, it sometimes occurs that cracks are generated in the coated film to be formed and coloring due to decomposition of the photo radical generator becomes remarkable. Further, when the addition amount becomes large, thermal decomposition of the photo radical generator causes deterioration of the electrical insulation of the cured product and release of gas, which sometimes become a problem in subsequent processes. Further, the resistance of the coated film to a photoresist stripper containing monoethanolamine or the like as a main component sometimes deteriorates.

Examples of the photo radical generator include azo-based, peroxide-based, acylphosphine oxide-based, alkylphenone-based, oxime ester-based, and titanocene-based initiators. Among them, alkylphenone-based, acylphosphine oxide-based and oxime ester-based initiators are preferred, and 2,2-dimethoxy-1,2-diphenylethan-1-one, 1-hydroxy-cyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)-benzyl]phenyl}-2-methylpropan-1-one, 2-methyl-1-(4-methylthiophenyl)-2-morpholinopropan-1-one, 2-benzyl-2-dimethylamino-1-(4-morpholinophenyl)-1-butanone, 2-(dimethylamino)-2-[(4-methylphenyl)methyl]-1-[4-(4-morpholinyl)-phenyl]-1-butanone, 2,4,6-trimethylbenzoyldiphenyl phosphine oxide, bis(2,4,6-trimethylbenzoyl)-phenyl-phosphine oxide, 1,2-octanedione, 1-[4-(phenylthio)-2-(O-benzoyloxime)], ethanone, 1-[9-ethyl-6-(2-methylbenzoyl)-9H-carbazol-3-yl]-1-(O-acetyloxime), and the like are included.

### (IV) Solvent

The composition according to the present invention comprises a solvent. This solvent is not particularly limited as long as it can uniformly dissolve or disperse the above-described alkali-soluble resin, the reflectance modifier, the polymerization initiator, and the additives that are optionally added. Examples of the solvent that can be used in the present invention include ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether and propylene glycol monoethyl ether; propylene glycol alkyl ether acetates such as PGMEA, propylene glycol monoethyl ether acetate and propylene glycol monopropyl ether acetate; aromatic hydrocarbons, such as benzene, toluene and xylene; ketones, such as methyl ethyl ketone, acetone, methyl amyl ketone, methyl isobutyl ketone and cyclohexanone; alcohols, such as ethanol, propanol, butanol, hexanol, cyclohexanol, ethylene glycol and glycerin; esters, such as ethyl lactate, ethyl 3-ethoxypropionate, methyl 3-methoxypropionate; and cyclic esters, such as γ-butyrolactone, and the like. Among them, it is preferable to use propylene glycol alkyl ether acetates or esters from the viewpoints of easy availability, easy handling and solubility of the polymer. From the viewpoint of coating properties and storage stability, the solvent ratio of the alcohol is preferably 5 to 80 mass %.

The solvent content of the composition according to the present invention can be freely adjusted according to the method for applying the composition, and the like. For example, when the composition is applied by spray coating, it is also possible to make the proportion of the solvent in the composition to be 90 mass % or more. In the case of slit coating, which is used for coating a large substrate, the solvent content is usually 60 mass % or more, and preferably 70 mass % or more. The properties of the composition of the present invention does not vary largely with the amount of solvent.

Although the composition according to the present invention essentially includes the above-described (I) to (IV), further compounds can be optionally combined. The materials that can be combined are as described below.

### (V) Compound Containing Two or More (Meth)Acryloyloxy Groups

The composition according to the present invention can further comprise a compound containing two or more (meth)acryloyloxy groups (hereinafter sometimes referred to as the (meth)acryloyloxy group-containing compound for simplicity). Here, the (meth)acryloyloxy group is a general term for the acryloyloxy group and the methacryloyloxy group. This compound is a compound that can form a crosslinked structure by reacting with the above-described (meth)acryloyloxy group-containing polysiloxane and the above-described alkali-soluble resin or the like. Here, in order to form a crosslinked structure, a compound containing two or more acryloyloxy groups or methacryloyloxy groups, which are reactive groups, is needed, and in order to form a higher-order crosslinked structure, it preferably contains three or more acryloyloxy groups or methacryloyloxy groups.

As such a compound containing two or more (meth)acryloyloxy groups, esters obtained by reacting (α) a polyol compound having two or more hydroxy groups with (β) two or more (meth)acrylic acids are preferably used. As the polyol compound (α), compounds having, as a basic skeleton, a saturated or unsaturated aliphatic hydrocarbon, aromatic hydrocarbon, heterocyclic hydrocarbon, primary, secondary or tertiary amine, ether or the like, and having, as substituents, two or more hydroxy groups are included. The polyol compound can contain other substituent, for example, a carboxy group, a carbonyl group, an amino group, an ether bond, a thiol group, a thioether bond, and the like, as long as the effects of the present invention are not impaired.

Preferred polyol compounds include alkyl polyols, aryl polyols, polyalkanolamines, cyanuric acid, and dipentaerythritol. Here, when the polyol compound (α) has three or more hydroxy groups, it is not necessary that all the hydroxy groups have reacted with (meth)acrylic acid, and they can be partially esterified. This means that the esters can have unreacted hydroxy group(s). As such esters, tris(2-acryloxyethyl) isocyanurate, dipentaerythritol hexa(meth)acrylate, tripentaerythritol octa(meth)acrylate, pentaerythritol tetra(meth)acrylate, dipropylene glycol diacrylate, tripropylene glycol diacrylate, trimethylolpropane triacrylate, polytetramethylene glycol dimethacrylate, trimethylolpropane trimethacrylate, ditrimethylolpropane tetraacrylate, tricyclodecane dimethanol diacrylate, 1,9-nonanediol diacrylate, 1,6-hexanediol diacrylate, 1,10-decanediol diacrylate, and the like are included. Among them, tris(2-acryloxyethyl) isocyanurate and dipentaerythritol hexaacrylate are preferred from the viewpoint of reactivity and the number of crosslinkable groups. Further, in order to adjust the shape of the formed pattern, two or more of these compounds can be combined. In particular, a compound containing three (meth)acryloyloxy groups and a compound containing two (meth)acryloyloxy groups can be combined.

Such a compound is preferably a molecule that is relatively smaller than the alkali-soluble resin from the viewpoint of reactivity. For this reason, the molecular weight thereof is preferably 2,000 or less, and more preferably 1,500 or less.

Although the content of the (meth)acryloyloxy group-containing compound is adjusted according to the type of the polymer or the (meth)acryloyloxy group-containing compound to be used, it is preferably 5 to 300 mass %, more preferably 20 to 100 mass %, based on the total mass of the alkali-soluble resin from the viewpoint of compatibility with resin. When a low-concentration developer is used, the content is preferably 20 to 200 mass %. Further, the (meth)acryloyloxy group-containing compounds can be used alone or in combination of two or more.

The content of the components other than (I) to (V) in the entire composition is preferably 30% or less, more preferably 20% or less, and further preferably 10% or less, based on the total mass of the composition.

### (VI) Other Additives

The composition according to the present invention can optionally comprise other additives. As such additives, a developer dissolution accelerator, a scum remover, an adhesion enhancer, a polymerization inhibitor, an antifoaming agent, a surfactant, a photosensitizing enhancing agent, a crosslinking agent, a curing agent, and the like are included.

The developer dissolution accelerator or scum remover has a function of adjusting the solubility of the formed coated film in the developer and preventing scum from remaining on the substrate after development. As such an additive, crown ether can be used. The crown ether having the simplest structure is represented by the general formula (—CH₂—CH₂—O—)ₙ. Preferred in the present invention are those in which n is 4 to 7. When x is set to be the total number of atoms constituting the ring and y is set to be the number of oxygen atoms contained therein, the crown ether is sometimes called x-crown-y-ethers. In the present invention, preferred is selected from the group consisting of crown ethers, wherein x=12, 15, 18 or 21, and y=x/3, and their benzo condensates and cyclohexyl condensates. Specific examples of more preferred crown ethers include 21-crown-7-ether, 18-crown-6-ether, 15-crown-5-ether, 12-crown-4-ether, dibenzo-21-crown-7-ether, dibenzo-18-crown-6-ether, dibenzo-15-crown-5-ether, dibenzo-12-crown-4-ether, dicyclohexyl-21-crown-7-ether, dicyclohexyl-18-crown-6-ether, dicyclo-hexyl-15-crown-5-ether, and dicyclohexyl-12-crown-4-ether. In the present invention, among them, most preferred is selected from 18-crown-6-ether and 15-crown-5-ether. The content thereof is preferably 0.05 to 15 mass %, more preferably 0.1 to 10 mass %, based on the total mass of the alkali-soluble resin.

The adhesion enhancer has an effect of preventing a pattern from peeling off due to stress applied after baking when a cured film is formed using the composition according to the present invention. As the adhesion enhancer, imidazoles, silane coupling agents, and the like are preferred. Among imidazoles, 2-hydroxybenzimidazole, 2-hydroxyethylbenzimidazole, benzimidazole, 2-hydroxyimidazole, imidazole, 2-mercaptoimidazole and 2-aminoimidazole are preferable, and 2-hydroxybenzimidazole, benzimidazole, 2-hydroxyimidazole and imidazole are particularly preferably used.

As the silane coupling agent, known ones are suitably used, and examples thereof include epoxy silane coupling agents, amino silane coupling agents, mercapto silane coupling agents, and the like. In particular, 3-glycidoxypropyltrimethoxysilane, 3-glycidoxypropyl-triethoxysilane, N-2-(aminoethyl)-3-aminopropyltrimethoxysilane, N-2-(aminoethyl)-3-aminopropyltri-ethoxysilane, 3-aminopropyltrimethoxysilane, 3-amino-propyltriethoxysilane, 3-ureidopropyltriethoxysilane, 3-chloropropyltriethoxysilane, 3-mercaptopropyltri-methoxysilane, 3-isocyanatopropyltriethoxysilane, and the like are preferred. These can be used alone or in combination of two or more, and the addition amount thereof is preferably 0.05 to 15 mass % based on the total mass of the alkali-soluble resin.

Further, as the silane coupling agent, a silane compound and siloxane compound having an acid group, or the like can be used. Examples of the acid group include a carboxy group, an acid anhydride group, a phenolic hydroxy group, and the like. When it contains a monobasic acid group such as a carboxy group or a phenolic hydroxy group, it is preferred that a single silicon-containing compound has a plurality of acid groups.

Exemplified embodiments of such a silane coupling agent include a compound represented by the formula (C):

XₙSi(OR³)₄₋ₙ (C)

or polymer obtained using it as a repeating unit. At this time, a plurality of repeating units having different X or R³ can be used in combination.

In the formula, R³ includes a hydrocarbon group, for example, an alkyl group such as a methyl group, an ethyl group, an n-propyl group, an isopropyl group, and an n-butyl group. In the general formula (C), a plurality of R³ are included, and each R³ can be identical or different.

As X, those having an acid group such as phosphonium, borate, carboxyl, phenol, peroxide, nitro, cyano, sulfo, and alcohol group are included, and those in which these acid groups are protected by acetyl, aryl, amyl, benzyl, methoxymethyl, mesyl, tolyl, trimethoxysilyl, triethoxysilyl, triisopropylsilyl or trityl group, and an acid anhydride group are included.

Among them, a compound having a methyl group as R³ and a carboxylic acid anhydride group as X, such as an acid anhydride group-containing silicone, is preferable. More particularly, a compound represented by the following formula (X-12-967C (trade name, Shin-Etsu Chemical Co., Ltd.)) or polymer containing a structure corresponding thereto in its terminal or side chain of a silicon-containing polymer such as silicone is preferred.

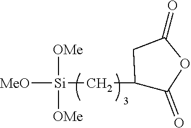

Further, a compound in which thiol, phosphonium, borate, carboxyl, phenol, peroxide, nitro, cyano, and an acid group such as sulfo group is provided at the terminal of dimethyl silicone is also preferable. As such a compound, compounds represented by the following formulae (X-22-2290AS and X-22-1821 (trade name in every case, Shin-Etsu Chemical Co., Ltd.)) are included.

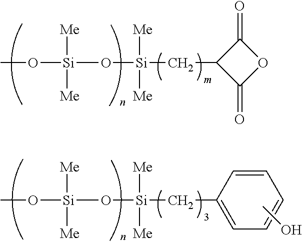

When the silane coupling agent has a silicone structure, if the molecular weight is too large, the compatibility with polysiloxane contained in the composition becomes poor, so that there is a possibility that there is an adverse effect such that the solubility in the developer does not improve, the reactive group remains in the film, and the chemical resistance that can withstand the subsequent process cannot be maintained. For this reason, the mass average molecular weight of the silane coupling agent is preferably 5,000 or less, and more preferably 4,000 or less. The content of the silane coupling agent is preferably 0.01 to 15 mass % based on the total mass of the alkali-soluble resin.

As the polymerization inhibitor, an ultraviolet absorber as well as nitrone, nitroxide radical, hydroquinone, catechol, phenothiazine, phenoxazine, hindered amine and derivatives thereof can be added. Among them, methylhydroquinone, catechol, 4-t-butylcatechol, 3-methoxycatechol, phenothiazine, chlorpromazine, phenoxazine, TINUVIN 144, 292 and 5100 (BASF) as the hindered amine, and TINUVIN 326, 328, 384-2, 400 and 477 (BASF) as the ultraviolet absorber are preferred. These can be used alone or in combination of two or more, and the content thereof is preferably 0.01 to 20 mass % based on the total mass of the alkali-soluble resin.

As the antifoaming agent, alcohols (C₁₋₁₈), higher fatty acids such as oleic acid and stearic acid, higher fatty acid esters such as glycerin monolaurate, polyethers such as polyethylene glycols (PEG) (Mn: 200 to 10,000) and polypropylene glycols (PPG) (Mn: 200 to 10,000), silicone compounds such as dimethyl silicone oil, alkyl-modified silicone oil and fluorosilicone oil, and organosiloxane-based surfactants described in detail below are included. These can be used alone or in combination of a plurality of these, and the content thereof is preferably 0.1 to 3 mass % based on the total mass of the alkali-soluble resin.

Further, the composition according to the present invention can optionally comprise a surfactant. The surfactant is added for the purpose of improving coating properties, developability, water repellency and oil repellency of film surface, and the like. Examples of the surfactant that can be used in the present invention include nonionic surfactants, anionic surfactants, and amphoteric surfactants.

Examples of the nonionic surfactant include, polyoxyethylene alkyl ethers, such as polyoxyethylene lauryl ether, polyoxyethylene oleyl ether and polyoxyethylene cetyl ether; polyoxyethylene fatty acid diester; polyoxyethylene fatty acid monoester; polyoxyethylene polyoxypropylene block polymer; acetylene alcohol; acetylene glycol; polyethoxylate of acetylene alcohol; acetylene glycol derivatives, such as polyethoxylate of acetylene glycol; fluorine-containing surfactants, such as Fluorad (trade name, 3M Japan Limited), Megafac (trade name, DIC Corporation), Surflon (trade name, AGC Inc.); or organosiloxane surfactants, such as KP341 (trade name, Shin-Etsu Chemical Co., Ltd.). Examples of the above-described acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-di-methyl-3-hexyne-2,5-diol, 2,5-di-methyl-2,5-hexanediol, and the like. Among these, Megafac RS series contributes to the improvement in water repellency and oil repellency of the film surface, and is therefore suitable for forming a film partition wall application.

Further, examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid, and the like.

Further, examples of the amphoteric surfactant include 2-alkyl-N-carboxymethyl-N-hydroxyethyl imidazolium betaine, lauric acid amide propyl hydroxysulfone betaine, and the like.

These surfactants can be used alone or as a mixture of two or more types, and the content thereof is preferably 0.005 to 1 mass %, more preferably 0.01 to 0.5 mass %, based on the total mass of the composition.

A photosensitizing enhancing agent can be optionally added to the composition according to the present invention. The photosensitizing enhancing agent preferably used in the composition according to the present invention includes coumarin, ketocoumarin and their derivatives, thiopyrylium salts, acetophenones, and the like, and particularly, p-bis(o-methylstyryl)benzene, 7-dimethylamino-4-methylquinolone-2,7-amino-4-methylcoumarin, 4,6-di-methyl-7-ethylaminocoumarin, 2-(p-dimethylamino-styryl)-pyridylmethyl-iodide, 7-diethylaminocoumarin, 7-diethylamino-4-methyl-coumarin, 2,3,5,6-1H,4H-tetrahydro-8-methyl-quinolizino-<9,9a,1-gh>coumarin, 7-diethylamino-4-trifluoromethylcoumarin, 7-dimethyl-amino-4-trifluoro-methylcoumarin, 7-amino-4-trifluoro-methylcoumarin, 2,3,5,6-1H,4H-tetrahydroquinolizino-<9,9a,1-gh>coumarin, 7-ethylamino-6-methyl-4-trifluoromethylcoumarin, 7-ethylamino-4-trifluoro-methylcoumarin, 2,3,5,6-1H,4H-tetrahydro-9-carbo-ethoxyquinolizino-<9,9a,1-gh>coumarin, 3-(2′-N-methylbenzimidazolyl)-7-N,N-diethylaminocoumarin, N-methyl-4-trifluoro-methylpiperidino-<3,2-g>coumarin, 2-(p-dimethylaminostyryl)-benzothiazolylethyl iodide, 3-(2′-benzimidazolyl)-7-N,N-diethylaminocoumarin, 3-(2′-benzothiazolyl)-7-N,N-diethylaminocoumarin, and sensitizing dyes such as pyrylium salts and thiopyrylium salts represented by the following chemical formula. By the addition of the sensitizing dye, patterning using an inexpensive light source such as a high-pressure mercury lamp (360 to 430 nm) becomes possible. The content thereof is preferably 0.05 to 15 mass %, more preferably 0.1 to 10 mass %, based on the total mass of the alkali-soluble resin.

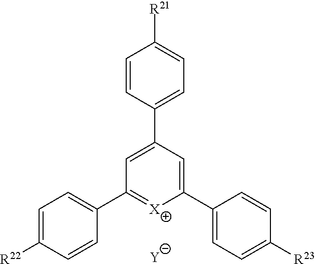

| X | R²¹ | R²² | R²³ | Y |
|---|---|---|---|---|
| S | OC₄H₉ | H | H | BF₄ |
| S | OC₄H₉ | OCH₃ | OCH₃ | BF₄ |
| S | H | OCH₃ | OCH₃ | BF₄ |
| S | N(CH₃)₂ | H | H | ClO₂ |
| O | OC₄H₉ | H | H | SbF₆ |

Further, as the photosensitizing enhancing agent, an anthracene skeleton-containing compound can be also used. In particular, a compound represented by the following formula is included.

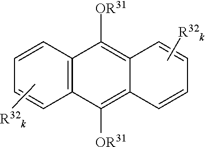

wherein, R³¹ each independently represents a substituent selected from the group consisting of an alkyl group, an aralkyl group, an allyl group, a hydroxyalkyl group, an alkoxyalkyl group, a glycidyl group, and a halogenated alkyl group,
R³² each independently represents a substituent selected from the group consisting of a hydrogen atom, an alkyl group, an alkoxy group, a halogen atom, a nitro group, a sulfonic acid group, a hydroxy group, an amino group, and a carboalkoxy group, and
k is each independently selected from 0 and an integer of 1 to 4.

When such a photosensitizing enhancing agent having an anthracene skeleton is used, its content is preferably 0.01 to 5 mass % based on the total mass of the alkali-soluble resin.

### <Method for Forming Cured Film>

The method for forming a cured film according to the present invention comprises applying the above-described composition on a substrate to form a film, exposing the film, and heating the film. The method for forming a cured film is described in process order as follows.

### (1) Application Process

First, the above-described composition is applied onto a substrate. Formation of the coating film of the composition in the present invention can be carried out by any method conventionally known as a method for applying a photosensitive composition. In particular, it can be freely selected from dip coating, roll coating, bar coating, brush coating, spray coating, doctor coating, flow coating, spin coating, slit coating, and the like. Further, as the substrate on which the composition is applied, a suitable substrate such as a silicon substrate, a glass substrate, a resin film, and the like can be used. Various semiconductor devices and the like can be formed on these substrates as needed. When the substrate is a film, gravure coating can also be utilized. If desired, a drying process can be additionally provided after applying the film. Further, if necessary, the applying process can be repeated once or twice or more to make the film thickness of the coating film to be formed as desired.

### (2) Pre-Baking Process

After forming the coating film of the composition by applying the composition, it is preferable to carry out pre-baking (heat treatment) of the coating film in order to dry the coating film and reduce the residual amount of the solvent in the coating film. The pre-baking process can be carried out at a temperature of generally 50 to 150° C., preferably 90 to 120° C., in the case of a hot plate, for 10 to 300 seconds, preferably 30 to 120 seconds and in the case of a clean oven, for 1 to 30 minutes.

### (3) Exposure Process

After forming a coating film, the coating film surface is then irradiated with light. As the light source to be used for the light irradiation, any one conventionally used for a pattern forming method can be used. As such a light source, a high-pressure mercury lamp, a low-pressure mercury lamp, a lamp such as metal halide and xenon, a laser diode, an LED and the like can be included. As the irradiation light, ultraviolet ray such as g-line, h-line and i-line is usually used. Except ultrafine processing for semiconductors or the like, it is general to use light of 360 to 430 nm (high-pressure mercury lamp) for patterning of several μm to several dozens of μm. The energy of the irradiation light is generally 5 to 2,000 mJ/cm², preferably 10 to 1,000 mJ/cm², although it depends on the light source and the film thickness of the coating film. If the irradiation light energy is lower than 5 mJ/cm², sufficient resolution cannot be obtained in some cases. On the other hand, when the irradiation light energy is higher than 2,000 mJ/cm², the exposure becomes excess and occurrence of halation is sometimes brought.

In order to irradiate light in a pattern shape, a general photomask can be used. Such a photomask can be freely selected from well-known ones. The environment at the time of irradiation is not particularly limited and can generally be set as an ambient atmosphere (in the air) or nitrogen atmosphere. Further, in the case of forming a film on the entire surface of the substrate, light irradiation can be performed over the entire surface of the substrate. In the present invention, the pattern film also includes such a case where a film is formed on the entire surface of the substrate.

### (4) Post Exposure Baking Process

After the exposure, to promote the reaction between the polymer in the film by the polymerization initiator, post exposure baking can be performed as necessary. Different from the heating process (6) to be described later, this heating treatment is performed not to completely cure the coating film but to leave only a desired pattern on the substrate after development and to make other areas capable of being removed by development.

When the post exposure baking is performed, a hot plate, an oven, a furnace, and the like can be used. The heating temperature should not be excessively high because it is not desirable for the acid in the exposed area, which is generated by light irradiation, to diffuse to the unexposed area. From such a viewpoint, the range of the heating temperature after exposure is preferably 40 to 150° C., and more preferably 60 to 120° C. Stepwise heating can be applied as needed to control the curing rate of the composition. Further, the atmosphere during the heating is not particularly limited and can be selected from in an inert gas such as nitrogen, under a vacuum, under a reduced pressure, in an oxygen gas, and the like, for the purpose of controlling the curing rate of the composition. Further, the heating time is preferably above a certain level in order to maintain higher the uniformity of temperature history in the wafer surface and is preferably not excessively long in order to suppress diffusion of the generated acid. From such a viewpoint, the heating time is preferably 20 seconds to 500 seconds, and more preferably 40 seconds to 300 seconds.

### (5) Developing Process

After post-exposure heating is optionally performed after exposure, the coating film can be developed. The present invention can be used for cases wherein development is not performed, that is, cases wherein patters are not formed, and when patterns are formed, development is performed. As the developer to be used at the time of development, any developer conventionally used for developing a photosensitive composition can be used. Preferable examples of the developer include an alkali developer which is an aqueous solution of an alkaline compound such as tetraalkylammonium hydroxide, choline, alkali metal hydroxide, alkali metal metasilicate (hydrate), alkali metal phosphate (hydrate), a sodium carbonate aqueous solution, ammonia, alkylamine, alkanolamine and heterocyclic amine, and a particularly preferable alkali developer is a tetramethylammonium hydroxide aqueous solution, a potassium hydroxide aqueous solution, a sodium hydroxide aqueous solution, or a sodium carbonate aqueous solution. In this alkali developer, a water-soluble organic solvent such as methanol and ethanol, or a surfactant can be further contained, if necessary. In the present invention, the development can be performed using a developer having a lower concentration than a 2.38 mass % TMAH developer that is usually used as a developer. Examples of such a developer include a 0.05 to 1.5 mass % TMAH aqueous solution, a 0.1 to 2.5 mass % sodium carbonate aqueous solution, and a 0.01 to 1.5 mass % potassium hydroxide aqueous solution. The developing time is usually 10 to 300 seconds, preferably 30 to 180 seconds. The developing method can also be freely selected from conventionally known methods. In particular, methods such as dipping in a developer (dip), paddle, shower, slit, cap coat, spray, and the like can be included. After the development with a developer, by which a pattern can be obtained, it is preferable that rinsing with water is carried out.

### (6) Heating Process

After development, the obtained pattern film is cured by heating. As the heating apparatus used for the heating process, the same one as used for the above-described post-exposure heating can be used. By this heating process, polymer A is colored, and the transparency of entire film is reduced, that is, the light shielding property is increased. Without wishing to be bound by theory, this is considered to be due to the oxidation of methylene groups in the repeating unit represented by formula (A) in polymer A. In order to further improve the light shielding properties, the heating temperature in this heating process is preferably 150 to 300° C., and more preferably 180 to 250° C. In this hearing process, curing of the coating film is accelerated. In case that the alkali-soluble resin includes polysiloxane, if the silanol group of polysiloxane remains, the chemical resistance of the cured film sometimes becomes insufficient, or dielectric constant of the cured film sometimes becomes higher. From such viewpoints, a relatively high temperature is generally selected as the heating temperature, and the heating temperature is preferably 150 to 300° C., and more preferably 180 to 280° C. Further, the heating time is not particularly limited and is generally 10 minutes to 24 hours, and preferably 30 minutes to 3 hours. In addition, this heating time is a time from when the temperature of the pattern film reaches a desired heating temperature. Usually, it takes about several minutes to several hours for the pattern film to reach a desired temperature from the temperature before heating.

The cured film thus formed exhibits the effects of the present invention as long as it has an average film thickness of 100 μm or less, and is preferably a film having that of 5 to 100 μm. It is more preferably 5 to 25 μm, and still more preferably 8 to 20 μm.

The average optical density (OD) of the cured film is preferably 1 or more at the wavelength of 400 to 700 nm. Here, the measurement of the optical density is performed using for example Spectrophotometer CM-5 (Konica Minolta, Inc.).

Regarding reflectance of the cured film, the average reflectance at wavelength 370 to 740 by SCI (Specular Component Included) method, in which diffuse reflectance is measured without removing the specular reflectance, is preferably 30 or more, more preferably 40 or more. The reflectance can be measured by, for example, Spectrophotometer CM-5 (Konica Minolta, Inc.).

The cured film according to the present invention has good light shielding properties and high reflectance, and can be used as a partition wall material having high reflectance (or high refractive index) of devices or an overcoat material. The color of the cured film is not particularly limited, and is preferably white. Since the cured film according to the present invention can be made thicker, it can be suitably used for micro LEDs, quantum dot displays, and organic electroluminescence devices that require a thicker partition wall material.

The present invention is described more particularly below with reference to Examples and Comparative Examples, but the present invention is not limited by these Examples and Comparative Examples at all.

Gel permeation chromatography (GPC) was measured using two columns of HLC-8220 GPC type high-speed GPC system (trade name, manufactured by Tosoh Corporation) and Super Multipore HZ-N type GPC column (trade name, manufactured by Tosoh Corporation). The measurement was performed using monodisperse polystyrene as a standard sample and tetrahydrofuran as an eluent, under the analytical conditions of a flow rate of 0.6 ml/min and a column temperature of 40° C.

### <Synthesis of Polysiloxane>

In a 2 L flask equipped with a stirrer, a thermometer and a condenser, 49.0 g of a 25 mass % TMAH aqueous solution, 600 ml of IPA and 4.0 g of water were charged, and then in a dropping funnel, a mixed solution of 68.0 g of methyltrimethoxysilane, 79.2 g of phenyltrimethoxysilane and 15.2 g of tetramethoxysilane was prepared. The mixed solution was added dropwise at 40° C., and stirred at the same temperature for 2 hours, and then neutralized by adding a 10 mass % HCl aqueous solution. 400 ml of toluene and 600 ml of water were added to the neutralized solution to separate into two layers, and the aqueous layer was removed. Further, after rinsing three times with 300 ml of water, the obtained organic layer was concentrated under reduced pressure to remove the solvent, and PGMEA was added to the concentrate to adjust the solid content concentration to be 35 mass %, thereby obtaining a polysiloxane solution.

The molecular weight (in terms of polystyrene) was measured by gel permeation chromatography and mass average molecular weight (hereinafter sometimes referred to as “Mw”) of the polysiloxane obtained was 1,700. Obtained polysiloxane solution was coated on a silicon wafer using a spincoater (MS-A100, MIKASA CO., LTD) so that the film thickness after prebaking becomes 2 μm, and the dissolution rate in 2.38 mass % TMAH aqueous solution was measured. The measured dissolution rate was 1200 Å/sec.

### <Synthesis of Acrylic Polymer A>

In a 1 L flask equipped with a stirrer, a thermometer, a condenser and a nitrogen gas introducing pipe, 16.4 g of azobisisobutyronitrile and 120 g of butanol were charged, and under a nitrogen gas atmosphere, the temperature was raised to an appropriate temperature, while referring to the 10-hour half-life temperature of the initiator. Separately from that, a mixture liquid was prepared by mixing 13.0 g of methacrylic acid, 46.5 g of KBM-502, 6.5 g of 2-hydroxyethyl methacrylate and 60.0 g of methyl methacrylate, and the mixed liquid was dropped into the above-described solvent for 4 hours. Thereafter, the resulting product was reacted for 3 hours to obtain an acrylic polymer A having Mw of 7,000.

### <Synthesis of Acrylic Polymer B>

In a 1 L flask equipped with a stirrer, a thermometer, a condenser and a nitrogen gas introducing pipe, 16.4 g of azobisisobutyronitrile and 120 g of butanol were charged, and under a nitrogen gas atmosphere, the temperature was raised to an appropriate temperature, while referring to the 10-hour half-life temperature of the initiator. Separately from that, a mixture liquid was prepared by mixing 5.16 g of methacrylic acid, 46.5 g of KBM-502, 6.5 g of 2-hydroxyethyl methacrylate and 70.08 g of methyl methacrylate, and the mixed liquid was dropped into the above-described solvent for 4 hours. Thereafter, the resulting product was reacted for 3 hours to obtain an acrylic polymer B having Mw of 7,350.

### Example 1

In a solution containing 15 parts by mass of the novolac polymer having two repeating units represented by below in 50% each based on the number of all repeating units contained in the novolac polymer, 30 parts by mass of above obtained polysiloxane, 35 parts by mass of above obtained acrylic polymer A and 35 parts by mass of above obtained acrylic polymer B, 1 parts by mass of polymerization initiator A (“NCI-831E”, ADEKA Corporation), 12 parts by mass of polymerization initiator B (“Omnirad 819”, IGM Resins B.V.), 50 parts by mass of dipentaerythritol hexa-acrylate (“A-DPH”, Shin-Nakamura Chemical Co., Ltd.), 0.3 parts by mass of surfactant (“Megafac RS-72A”, DIC Corporation) and 44.6 parts by mass of titanium oxide (“TiO₂”, Sigma-Aldrich, titanium dioxide particles having primary particle diameter of 50 to 100 nm) were added, and further PGMEA was added to prepare a 30 mass % solution, and after stirring, to obtain a composition of Example 1.

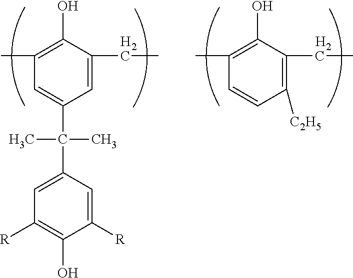

(Wherein, one of two R is methyl.)
Novolac polymer (Aica Kogyo Co., Ltd., mass average molecular weight 9,750)

### Examples 2 to 9, Comparative Examples 1 and 2

Compositions for which the formulation of Example 1 was each changed as shown in Table 1 were prepared. In the table, numerical values of the components indicate parts by mass.

TABLE 1

| | | | | | | | | | | | | Comparative | |
|---|---|---|---|---|---|---|---|---|---|---|---|---|---|
| | | | Example | | | | | | | | | Example | |
| | | | 1 | 2 | 3 | 4 | 5 | 6 | 7 | 8 | 9 | 1 | 2 |
| Comp- | Alkali- | Novolac polymer | 15 | 5 | 5 | 5 | 5 | 5 | 5 | 30 | 5 | — | — |
| onent | soluble | Polysiloxane | 30 | 30 | 30 | 30 | 30 | — | 100 | 30 | 30 | 30 | 30 |
| | resin | Acrylic polymer A | 35 | 35 | 35 | 35 | 35 | 50 | — | 35 | 35 | 35 | 35 |
| | | Acrylic polymer B | 35 | 35 | 35 | 35 | 35 | 50 | — | 35 | 35 | 35 | 35 |
| | | Cyclic olefin | — | — | — | — | — | — | — | — | — | — | 10 |
| | | polymer | | | | | | | | | | | |
| | Reflectance modifier | | 44.6 | 42.1 | 21.0 | 63.1 | 84.2 | 42.1 | 42.1 | 48.3 | 105.2 | 40.8 | 43.3 |
| | Polymerization initiator A | | 1 | 1 | 1 | 1 | 1 | 1 | 1 | 1 | 1 | 1 | 1 |
| | Polymerization initiator B | | 12 | 12 | 12 | 12 | 12 | 12 | 12 | 12 | 12 | 12 | 12 |
| | Surfactant | | 0.3 | 0.3 | 0.3 | 0.3 | 0.3 | 0.3 | 0.3 | 0.3 | 0.3 | 0.3 | 0.3 |
| | (meth)acryloyloxy group- | | 50 | 50 | 50 | 50 | 50 | 50 | 50 | 50 | 50 | 50 | 50 |
| | containing compound | | | | | | | | | | | | |
| Evalu- | O D value | | 2.06 | 1.35 | 1.23 | 1.38 | 1.41 | 1.36 | 1.37 | 2.15 | 1.42 | 0.72 | 0.22 |
| ation | Reflecta- | SCI | 51 | 54 | 50 | 60 | 64 | 52 | 56 | 49 | 64 | 8 | 45 |
| | nce(%) | SCE | 49 | 51 | 47 | 58 | 62 | 48 | 52 | 47 | 62 | 8 | 42 |

| | | | | | | | | | | | |
|---|---|---|---|---|---|---|---|---|---|---|---|
| Pattern formation at lOum | A | A | A | A | A | A | A | A | B | A | C |

In the table:

Cyclic olefin polymer is represented by the following structure (mass average molecular weight 11,600),

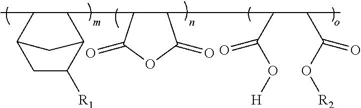

(wherein R1=Me, R2=H),

other components are as described in Example 1.

Each of the obtained compositions was coated on an alkali-free grass by spin coating, and after the coating, the coated film was prebaked on a hot plate at 100° C. for 90 seconds so as to prepare an average film thickness of 10 μm. Using a mask of 10 μm contact hall (C/H) patterns, exposure was performed with 200 mJ/cm² using an i-line exposure machine, development was performed using a 2.38% TMAH aqueous solution, and rinsing with pure water was performed for 30 seconds. Then, it was heated in air at 250° C. for 30 minutes. The obtained patterns were observed by SEM in cross-section and evaluated as follows. The obtained results are as shown in Table 1.

A: Patterns were formed and no peeling was observed.
B: Patterns were formed and peeling was partially observed.
C: The film was dissolved and a pattern could not be formed.

Each of the obtained compositions was coated on an alkali-free grass by spin coating, and after the coating, the coating film was prebaked on a hot plate at 100° C. for 90 seconds so as to prepare an average film thickness of 10 μm. After the coating film was heated in air at 250° C. for 30 minutes, the transmittance was measured using a Spectrophotometer CM-5 (Konica Minolta, Inc.), and it was converted into the OD. The obtained OD varues are as shown in Table 1.

Each of the obtained compositions was coated on an alkali-free grass by spin coating, and after the coating, the coated film was prebaked on a hot plate at 100° C. for 90 seconds so as to prepare an average film thickness of 10 μm. Then, exposure was performed with 200 mJ/cm² using an i-line exposure machine, development was performed using a 2.38% TMAH aqueous solution, and rinsing with pure water was performed for 30 seconds. Then, it was heated in air at 250° C. for 30 minutes. Then, the average reflectance at wavelength 370 to 740 nm by SCI method and SCE (Specular Component Excluded) method was measured using Spectrophotometer CM-5 (Konica Minolta, Inc.). The obtained reflectance are as shown in Table 1.

1.-12. (canceled)

13. A negative type photosensitive composition comprising
(I) an alkali-soluble resin comprising a polymer comprising a repeating unit represented by formula (A): 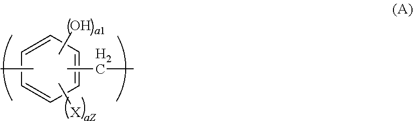
wherein,
X is each independently a C₁₋₂₇ substituted or unsubstituted hydrocarbon group,
a1 is 1 to 2, and
a2 is 0 to 3,
(II) a reflectance modifier,
(III) a polymerization initiator, and
(IV) a solvent.

14. The composition according to claim 13, wherein at least one X is
-L-Ar
wherein,
L is a C₁₋₈ linear or branched alkylene, and
Ar is a C₆₋₂₂ substituted or unsubstituted aryl.

15. The composition according to claim 13, wherein the alkali-soluble resin further comprises a polysiloxane and/or an acrylic polymer.

16. The composition according to claim 15, wherein the polysiloxane comprises a repeating unit represented by formula (Ia): 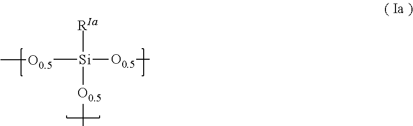
wherein,
R^{Ia} represents hydrogen, a C₁₋₃₀ linear, branched or cyclic, saturated or unsaturated, aliphatic hydrocarbon group or aromatic hydrocarbon group,
the aliphatic hydrocarbon group and the aromatic hydrocarbon group are each unsubstituted or substituted with fluorine, hydroxy, or C₁₋₈ alkoxy, and
in the aliphatic hydrocarbon group and the aromatic hydrocarbon group, methylenes are not replaced, or one or more methylene is replaced with oxy, imino or carbonyl, provided that R^{Ia} is neither hydroxy nor alkoxy.

17. The composition according to claim 13, wherein the reflectance modifier is selected from at least one of the groups consisting of alumina, magnesium oxide, antimony oxide, titanium oxide, titanium oxynitride, titanium nitride, zirconium oxide, aluminum hydroxide, magnesium hydroxide, barium sulfate, magnesium carbonate, and barium carbonate.

18. The composition according to claim 13, wherein the content of the reflectance modifier is 10 to 150 mass % based on the total mass of the alkali-soluble resin.

19. The composition according to claim 13, further comprising (V) a compound containing two or more (meth)acryloyloxy groups.

20. A method for producing a cured film comprising applying the composition according to claim 13 on a substrate to form a film, exposing the film, and heating the film.

21. The method according to claim 20, wherein the heating temperature is 150 to 300° C.

22. A cured film produced by the method according to claim 20.

23. The cured film according to claim 22, wherein the optical density (OD) is 1 or more.

24. A device comprising the cured film according to claim 22.
